(19) United States
(12) Patent Application Publication
(10) Pub. No.: US 2018/0054192 A1
(43) Pub. Date: Feb. 22, 2018

(54) PHASE INTERPOLATOR

(71) Applicant: Realtek Semiconductor Corporation, Hsinchu (TW)

(72) Inventor: Chien-Wen CHEN, Hsinchu City (TW)

(21) Appl. No.: 15/679,177

(22) Filed: Aug. 17, 2017

(30) Foreign Application Priority Data
Aug. 18, 2016 (TW) 105126416

(51) Int. Cl. H03K 5/08; H03K 5/13

(52) U.S. Cl. CPC H03K 5/088; H03K 2005/00286; H03K 5/13

(57) ABSTRACT

A phase interpolator includes differential pairs, a switching circuit, an output stage, and a correction circuit. The differential pairs generate a first signal and a second signal according to a first group of input signals and a second group of input signals. The switching circuit is turned on or turned off, according to control signals, to transmit the first signal and the second signal to a current source circuit, in order to control a value of the first signal and a value of the second signal. The output stage generates a first output signal according to the first signal and the second signal. The correction circuit provides and stables a common mode voltage of the first output signal according to the first output signal.

### RELATED APPLICATIONS

This application claims priority to Taiwan Application Serial Number, 105126416, filed Aug. 18, 2016, which is herein incorporated by reference.

### BACKGROUND

### Technical Field

The present disclosure relates to an integrated circuit. More particularly, the present disclosure relates to a correction circuit for a phase interpolator.

### Description of Related Art

Phase interpolators are commonly utilized in communication systems for synchronizing operational signals in the communication systems. With growing demands, which include, for example, higher speed, for communication systems, requirements for accuracy and a speed of the phase interpolators become higher. In current approaches, the driving abilities for a rising current and a falling current in the phase interpolators cannot be consistent with each other. As such, the accuracy of the phase interpolators cannot be improved.

### BRIEF DESCRIPTION OF THE DRAWINGS

FIG. 1 is a schematic diagram of a phase interpolator according to one embodiment of the present disclosure.

FIG. 2A is a circuit diagram of the correction circuit in FIG. 1, according to one embodiment of the present disclosure.

FIG. 2B is a circuit diagram of the correction circuit in FIG. 1, according to another embodiment of the present disclosure.

FIG. 3 is a schematic diagram of a part of a phase interpolator according to one embodiment of the present disclosure.

FIG. 4 is a schematic diagram of a part of a phase interpolator according to one embodiment of the present disclosure.

### DETAILED DESCRIPTION

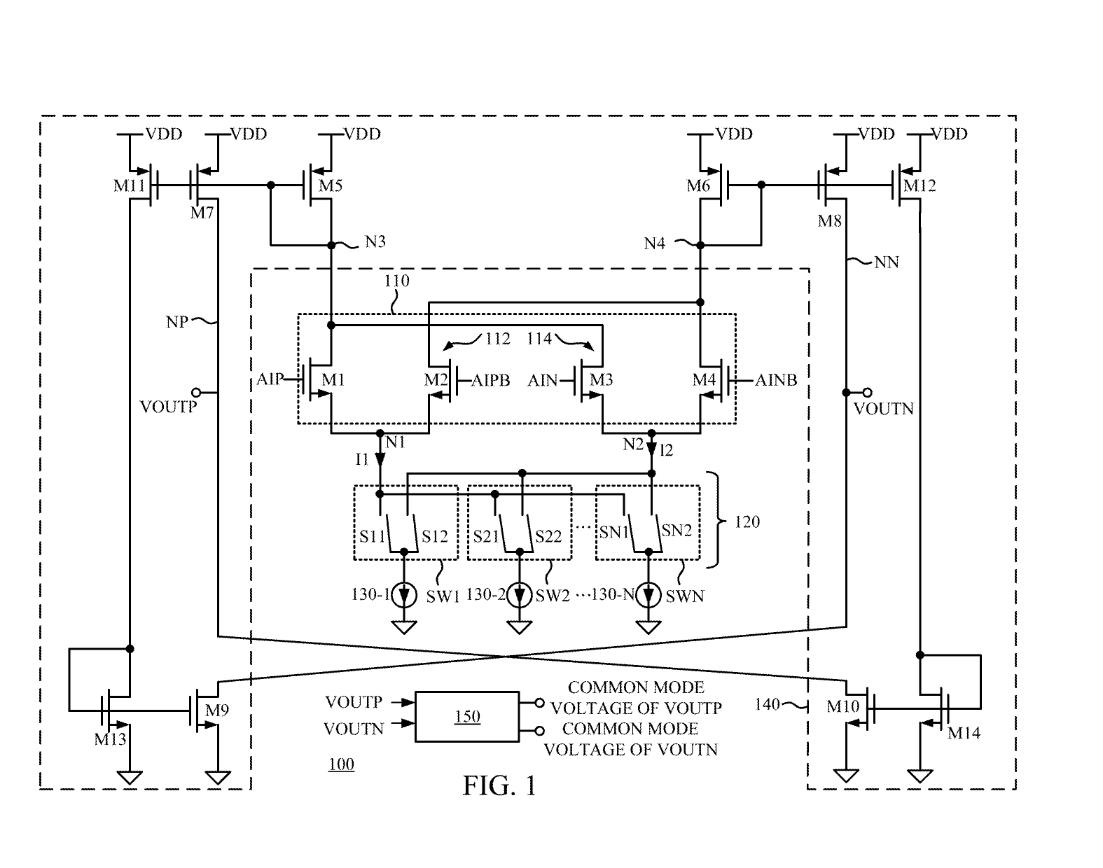

Referring to FIG. 1, a phase interpolator 100 includes an input stage 110, a switching circuit 120, current source circuits 130-1-130-N, and an output stage 140.

The input stage generates a signal I1 and a signal I2 according to a group of input signals (AIP, AIPB) and a group of input signals (AIN, AINB). In this embodiment, the input stage 110 includes differential pairs 112 and 114. The differential pair 112 includes transistors M1 and M2. The transistor M1 and the transistor M2 are configured to generate the signal I1 at a node N1 according to the input signal AIP and the signal AIPB, respectively. As shown in FIG. 1, a first terminal, i.e., node N3, of the transistor M1 is coupled to the output stage 140, a second terminal of the transistor M2 is coupled to the node N1, and a control terminal of the transistor M1 receives the input signal AIP. A first terminal, i.e., node N4, of the transistor M2 is coupled to the output stage 140, a second terminal of the transistor M2 is coupled to the node N1, and a control terminal of the transistor M2 receives the input signal AIPB.

Furthermore, the differential pair 114 includes transistors M3 and M4. A first terminal of the transistor M3 is coupled to the node N3, a second terminal of the transistor M3 is coupled to the node N2, and a control terminal of the transistor M3 receives the input signal AIN. A first terminal of the transistor M4 is couple to the node N4, a second terminal of the transistor M4 is coupled to the node N2, and a control terminal of the transistor M4 receives the input signal AINB. With the above arrangements, the differential pair 112 and the differential pair 144 can generate different values of the signals I1 and I2 according to the corresponding input signals AIP, AIPB, AIN, and AINB. As a result, the output stage 140 can generate output signals VOUTP and VOUN that have corresponding phases based on different values of the signals I1 and I2.

The switching circuit 120 is configured to be selectively turned on or turned off according to control signals (not shown), in order to transmit the signals I1 and I2 to at least corresponding one of the current source circuits 130-1-130-N. In this embodiment, the current source circuits 130-1-130-N can be implemented with current mirror circuits, but the present disclosure is not limited thereto.

The switching circuit 120 includes groups of switches SW1-SWN. Taking the groups of switches SW1 as an example, the group of switches SW1 includes a switch S11 and a switch S12. A first terminal of the switch S11 is coupled to the node N1, a second terminal of the switch S11 is coupled to the current source circuit 130-1, and a control terminal of the switch S11 is configured to receive a first control signal (not shown). A first terminal of the switch S12 is coupled to the node N2, a second terminal of the switch S12 is coupled to the current source circuit 130-1, and a control terminal of the switch S12 is configured to receive a second control signal (not shown). Arrangements between the rest groups of switches SW2-SWN and the current source circuits 130-2-130-N are the same as the arrangement of the group of switches SW1 and the current source circuit 130-1, and thus the repetitious descriptions are not given herein.

Internal switches (e.g., switches S11-S12) of the groups of switches SW1-SWN can be turned on or turned off via control signals. With such the arrangements, the signals I1 and I2 can be transmitted to at least one corresponding one of the current source circuits 130-1-130-N via the turn-on switch in the groups of switches SW1-SWN. In this embodiment, the values of the signals I1 and I2 can be controlled by the internal switches of the groups of switches SW1-SWN. Taking the group of switches SW1 as an example, the current source circuit 130-1 pulls corresponding currents from the node N1 and the node N2 based on the turn-on statuses of the switches S11 and S12. As the nodes N1 and N2 are coupled to at least corresponding one of the groups of the switches SW1-SWN, the values of the signals I1 and I2 are adjusted to different values according to the corresponding currents. Effectively, by determining the turn-on statuses of the switches in the groups of switches SW1-SWN, a conducting path is formed between the current source circuits 130-1-130-N and the node N1/N2. Accordingly, the values of the signals I1 and I2 are adjusted. As a result, the phase interpolator 100 can generate the output signals VOUTP and VOUTN that have different phases according to the signals I1 and I2.

The output stage 140 provides at least one active load to generate the output signals VOUTP and VOUTN according to the signals I1 and I2. In the example of FIG. 1, in this embodiment, the output stage 140 includes transistors M5-M14. A first terminal of the transistor M5 receives a voltage VDD, and both of a second terminal and a control terminal of the transistor M5 are coupled to the node N3. A first terminal of the transistor M6 receives the voltage VDD, and both of a second terminal and a control terminal of the transistor M6 are coupled to the node N4. A first terminal of the transistor M7 receives the voltage VDD, a second terminal (i.e., node NP) of the transistor M7 generates the output signal VOUTP, and a control terminal of the transistor M7 is coupled to the node N3. A first terminal of the transistor M8 receives the voltage VDD, a second terminal (i.e., node NN) of the transistor M8 generates the output signal VOUTN, and a control terminal of the transistor M8 is coupled to the control terminal of the transistor M6.

A first terminal of the transistor M9 is coupled to the node NN, a second terminal of the transistor M9 is coupled to ground, and a control terminal of the transistor M9 is coupled to a control terminal of the transistor M13. A first terminal of the transistor M10 is coupled to the node NP, a second terminal of the transistor M10 is coupled to ground, and a control terminal of the transistor M10 is coupled to a control terminal of the transistor M14.

A first terminal of the transistor M11 receives the voltage VDD, a second terminal of the transistor M11 is coupled to a first terminal of the transistor M13, and a control terminal of the transistor M11 is coupled to the node N3. A first terminal of the transistor M12 receives the voltage VDD, a second terminal of the transistor M12 is coupled to a first terminal of the transistor M14, and a control terminal of the transistor M12 is coupled to the node N4. A second terminal of the transistor M13 is coupled to ground, and a control terminal of the transistor M13 is coupled to the first terminal of the transistor M13. A second terminal of the transistor M14 is coupled to ground, and a control terminal of the transistor M14 is coupled to the first terminal of the transistor M14.

With such the arrangement, when the input stage 110 generates the signals I1-I2 according to the input signals AIP, AIPB, AIN, and AINB, the transistors M5 and M6 thus mirror the corresponding currents to the switches M7 and M8, in order to generate the output signals VOUTP and VOUTN. Moreover, as shown in FIG. 1, the transistors M1-M10 form differential circuit architecture that is fully symmetrical. With the differential circuit architecture, the values of the current at rising or falling of the output signals VOUTP and VOUTN can be identical with one another. As a result, the output accuracy of the phase interpolator 100 can be improved.

In this embodiment, the phase interpolator 100 further includes a correction circuit 150. The correction circuit 150 provides and stabilizes a common mode voltage of the output signal VOUTP according to the output signal VOUTP, and provides and stabilizes a common mode voltage of the output signal VOUTN according to the output signal VOUTN. With the correction circuit 150, the common mode voltages of the output signals VOUTN and VOUTP can be corrected to a stabilized voltage level. As a result, the accuracy of both of the output signals VOUTN and VOUTP, which are generated from an interpolation of the phase interpolator 100, can be improved.

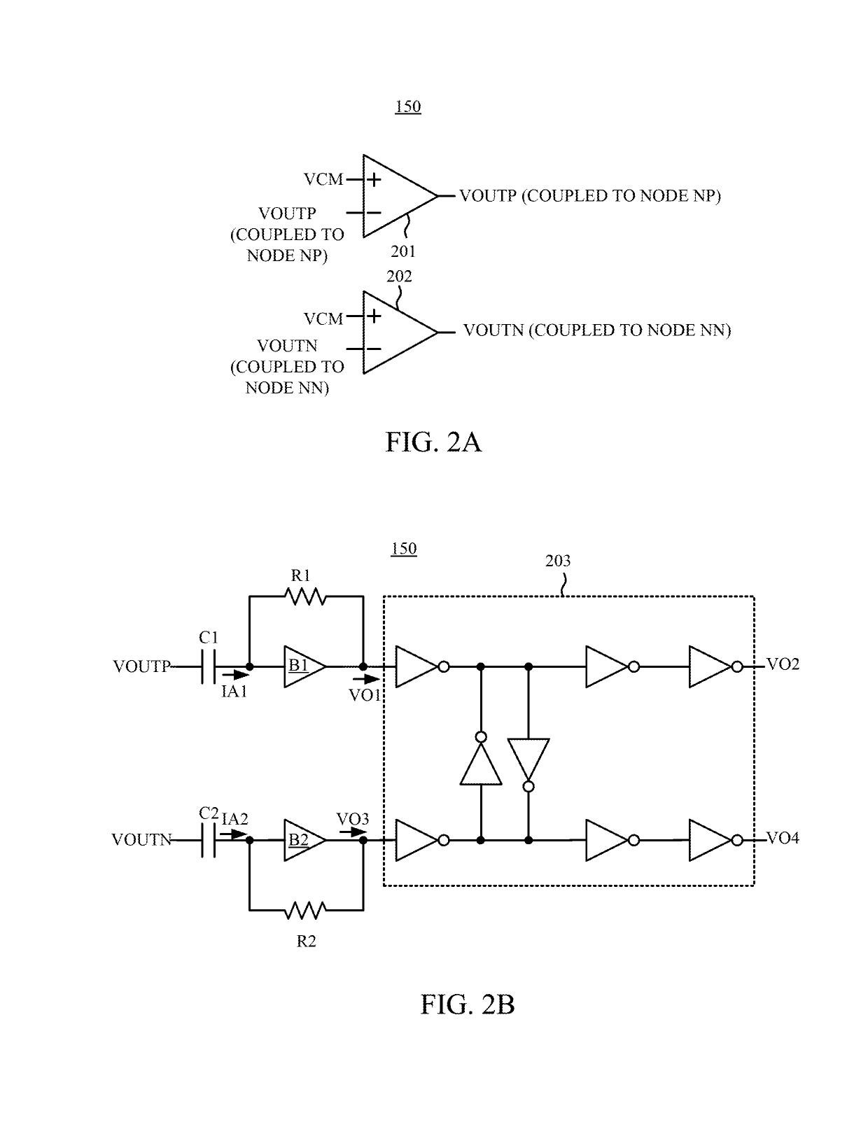

Referring to FIG. 2A, in this embodiment, the correction circuit 150 can be implemented with a negative feedback circuit. In this embodiment, the correction circuit 150 includes an amplifier 201 and an amplifier 202. The amplifier 201 generates a common mode voltage of the output signal VOUTP according to the output signal VOUTP. For example, a positive input terminal of the amplifier 201 receives a predetermined voltage VCM, and a negative terminal of the amplifier 201 is coupled to the node NP to receive the output signal VOUTP. An output terminal of the amplifier 201 generates the common mode voltage of the output signal VOUTP. With such an arrangement, the amplifier 201 can output a voltage that is substantially the same as the predetermined voltage VCM according to the output signal VOUTP and the predetermined voltage VCM, and configure the voltage as the common mode voltage of the output signal VOUTP.

Similarly, the amplifier 202 generates a common mode voltage of the output signal VOUTN according to the output signal VOUTN. For example, a positive input terminal of the amplifier 202 receives the predetermined voltage VCM, and a negative terminal of the amplifier 202 is coupled to the node NN to receive the output signal VOUTN. An output terminal of the amplifier 202 generates the common mode voltage of the output signal VOUTN. With such an arrangement, the amplifier 202 can output a voltage that is substantially the same as the predetermined voltage VCM according to the output signal VOUTN and the predetermined voltage VCM, and configure it as the common mode voltage of the output signal VOUTN. Effectively, the amplifiers 201 and 202 are arranged as a negative feedback circuit of the output stage 140, in order to converge levels of the two nodes (i.e., nodes NN and NP) of the output stage 140 toward to the predetermined voltage VCM.

Referring to FIG. 2B, in this embodiment, the correction circuit 150 can be implemented with an AC-coupled circuit. In the example of FIG. 2B, in this embodiment, the AC-coupled circuit includes capacitors C1-C2, resistors R1-R2, buffers B1-B2, and a buffering output circuit 203. The capacitor C1 is coupled to the second terminal of the transistor M7 to receive the output signal VOUTP. The capacitor C1 filters a DC-component of the output signal VOUTP to output an AC signal IA1, and provides the common mode voltage of the output signal VOUTP. The resistor R1 generates a DC voltage (not shown) according to the AC signal IA1. The buffer B1 generates the output signal VO1 based on the AC signal IA1. The buffering output circuit 203 generates the output signal VO2 based on the common mode voltage generated from the resistor R1 and the output signal VO1.

Similarly, the capacitor C2 filters a DC-component of the output signal VOUTN to output an AC signal IA2. The resistor R2 generates a DC voltage (not shown) according to the AC signal IA2, and provides the common mode voltage of the output signal VOUTN. The buffer B2 generates the output signal VO3 based on the AC signal IA2. The buffering output circuit 203 generates the output signal VO4 based on the common mode voltage generated from the resistor R2 and the output signal VO3. In this embodiment, the resistance values of the resistor R1-R2 can be determined according to gain and bandwidth. An expected common mode voltage value is determined by resistor self-bias definition. In this embodiment, the buffering output circuit 203 can be implemented by buffers and/or latches.

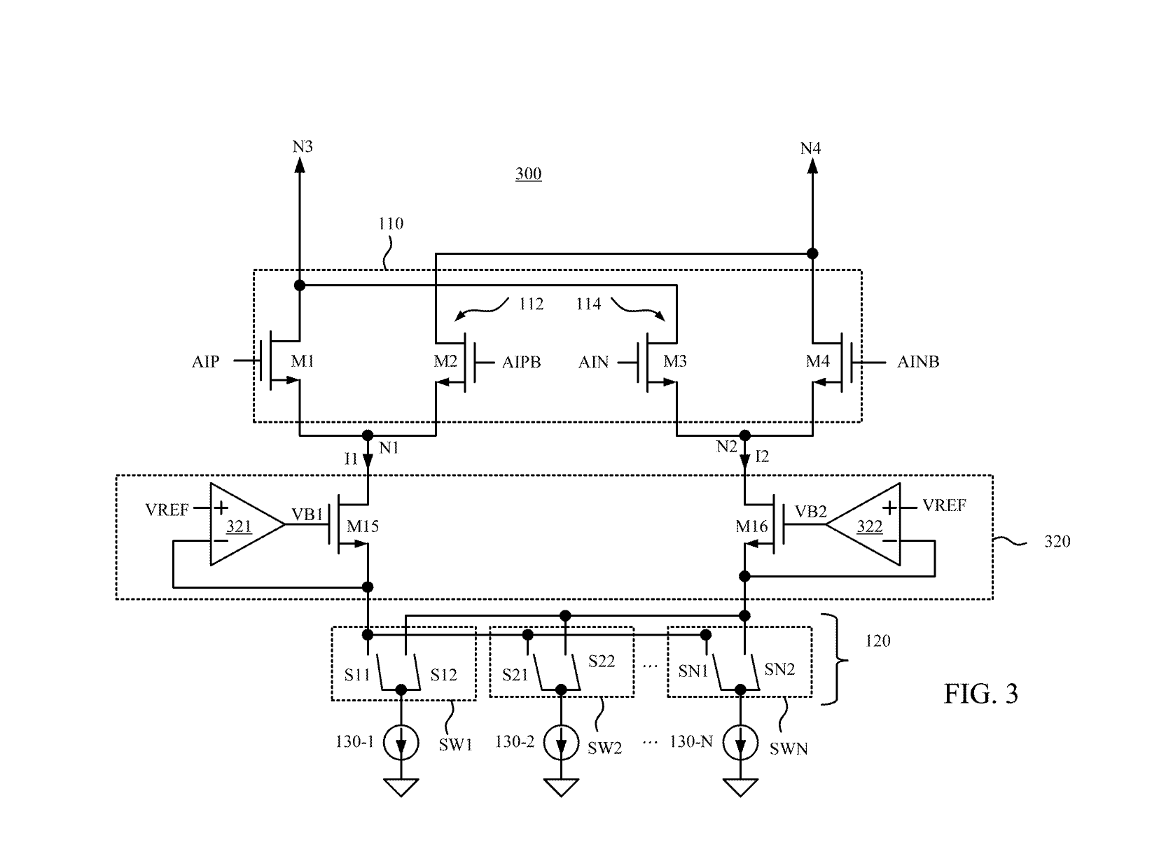

Reference is made to FIG. 3. FIG. 3 only shows a part of the main circuit diagram of the phase interpolator 300. The rest circuits in the phase interpolator 300 can be understood with reference to FIG. 1.

Compared with FIG. 1, the phase interpolator 300 further includes a regulation circuit 320. In this embodiment, the regulation circuit 320 is configured to increase equivalent impedances to which the current source circuits 130-1-130-N correspond, in order to improve the operational stability and accuracy of the current source circuits 130-1-130-N.

In the example of FIG. 3, in this embodiment, the current source circuits 130-1-130-N include transistors M15-M16 and amplifiers 321-322. A first terminal of the transistor M15 is coupled to the node N1 to receive the signal I1, and a second terminal of the transistor M15 is coupled to one terminal of the switching circuit (i.e., first terminals of the switch S11-SN1) to transmit the signal I1. A control terminal of the transistor M15 receives a bias voltage VB1. A first terminal of the transistor M16 is coupled to the node N2 to receive the signal I2, and a second terminal of the transistor M16 is coupled to another terminal of the switching circuit (i.e., first terminals of the switches S12-SN2) to transmit the signal I2. A control terminal of the transistor M16 receives a bias voltage VB2.

Furthermore, the amplifier 321 generates the bias voltage VB1 according to a voltage level of the second terminal of the transistor M15 and a reference voltage VREF. The amplifier 322 generates the bias voltage VB2 according to a voltage level of the second terminal of the transistor M16 and the reference voltage VREF.

With such the arrangement, the amplifier 321 is configured as a negative feedback circuit for the transistor M15, in order to stable the voltage variation across two terminals of the transistor M15. Effectively, the output impedances of the current source circuits 130-1-130-N are increased, such that the operations of the current source circuits 130-1-130-N can be more stable, and the accuracy of the current of those circuits are also improved. Similarly, the amplifier 322 is also configured to as a negative feedback circuit for the transistor M16. The operations of the amplifier 322 are similar with the operations of the amplifier 321, and thus the repetitious descriptions are not given here.

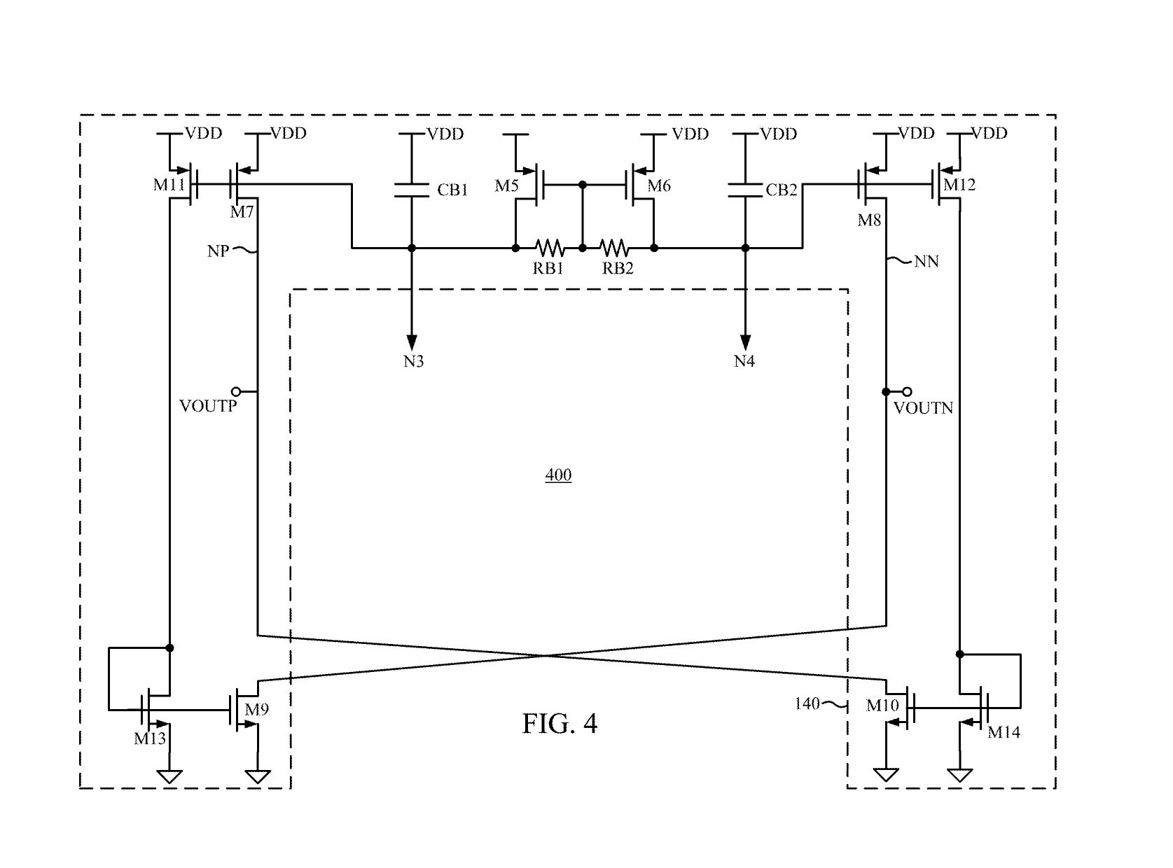

Reference is made to FIG. 4. FIG. 4 only shows a part of the main circuit diagram of the phase interpolator 400. The rest circuits in the phase interpolator 300 can be understood with reference to FIG. 1.

Compared with FIG. 1, the output stage 140 of the phase interpolator 400 employs two resistors RB1 and RB2 as load of the input stage 110. In this embodiment, a resistance value of the resistor RB1 is set to be less than an output impedance of the transistor M5, and a resistance value of the resistor RB2 is set to be less than an output impedance of the transistor M6. As a result, the resistors RB1 and RB2 will be considered as main loads of the input stage 110. Compared with the output stage 140 in FIG. 1, the impacts, which are introduced from nonlinear signal components, on the linearity of the output stage 140 in FIG. 4 can be much lower. Accordingly, the linearity of the gain or the bandwidth of the phase interpolator 400 can be improved.

In this embodiment, capacitors CB1 and CB2 are configured as capacitors, which have a filtering function and a voltage stabilization function, of an interpolative filtering circuit. As shown in FIG. 4, a first terminal of the capacitor CB1 receives the voltage VDD, and a second terminal of the capacitor CB1 is coupled to the second terminal of the switch M5. A first terminal of the capacitor CB2 receives the voltage VDD, and a second terminal of the capacitor CB2 is coupled to the second terminal of the switch M6. In this embodiment, the capacitors CB1 and CB2 can be implemented with transistors, in which first terminals and the second terminals of the transistors receive the voltage VDD, and control terminals of the transistors are coupled to the node N3 and/or the node N4.

In various embodiments, the capacitors CB1 and CB2 can be selectively employed according to practical requirements.

The correction circuit 150, the regulation circuit 320, and the output stage 140 in various embodiments above can be selectively employed in the phase interpolator 100 according to practical applications. For example, when the accuracy of a signal outputted from the phase interpolator 100 is critical, all of the correction circuit 150, the regulation circuit 320, and the output stage 140 can be employed. Alternatively, when the requirement of the accuracy of a signal outputted from the phase interpolator 100 is relatively lower, only one of the correction circuit 150, the regulation circuit 320, and the output stage 140 can be employed. Therefore, various phase interpolators that employs at least one of the correction circuit 150, the regulation circuit 320, and the output stage 140 in the embodiments above are also within the contemplated scope of the present disclosure.

As discussed above, the phase interpolator provided in the present disclosure can employ correction mechanisms to improve an accuracy of the phase interpolator, in order to obtain an output signal having a high accuracy.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A phase interpolator, comprising:
a plurality of differential pairs configured to generate a first signal and a second signal according to a first group of input signals and a second group of input signals;
a switching circuit configured to transmit the first signal and the second signal to a current source circuit and control a value of the first signal and a value of the second signal according to a plurality of control signals;
an output stage configured to generate a first output signal according to the first signal and the second signal; and
a correction circuit configured to provide a common mode voltage of the first output signal according to the first output signal.

2. The phase interpolator of claim 1, wherein the correction circuit comprises:
an amplifier coupled to the output stage, and configured to generate the common mode voltage according to the first output signal and a predetermined voltage.

3. The phase interpolator of claim 1, wherein the correction circuit comprises:
a capacitor configured to receive the first output signal, and to output an AC signal;
a self-bias resistor configured to generate the common mode voltage according to the AC signal;
a buffer configured to generate a second output signal according to the AC signal; and
a buffering output circuit configured to output a third output signal based on the common mode voltage and the second output signal.

4. The phase interpolator of claim 1, wherein the differential pairs comprise a first differential pair and a second differential pair, the first differential pair is configured to generate the first signal according to the first group of input signals, the second differential pair is configured to generate the second signal according to the second group of input signals, and the switching circuit comprises:
a first switch configured to be selectively turned on or turned off according a first one of the control signals, in order to transmit the first signal from the first differential pair to the current source circuit; and
a second switch configured to be selectively turned on or turned off according a second one of the control signals, in order to transmit the second signal from the second differential pair to the current source circuit.

5. The phase interpolator of claim 1, further comprising:
a regulation circuit configured to stable the switching circuit and the current source circuit.

6. The phase interpolator of claim 5, wherein the regulation circuit comprises:
a first transistor coupled to the switching circuit at an node, and configured to transmit the first signal to the switching circuit based on a bias voltage; and
a first amplifier configured to generate the bias voltage according to a voltage level of the node and a reference voltage.

7. The phase interpolator of claim 1, wherein the output stage is configured to provide an active load, in order to generate the first output signal according to the first signal and the second signal.

8. The phase interpolator of claim 1, wherein the differential pairs comprise a first differential pair and a second differential pair, the first differential pair is configured to generate the first signal according to the first group of input signals, the second differential pair is configured to generate the second signal according to the second group of input signals, a first terminal of the first differential pair is coupled to a first terminal of the second differential pair, a second terminal of the first differential pair is coupled to a second terminal of the second differential pair, and the output stage is further configured to generate a second output signal according to the first signal and the second signal.

9. The phase interpolator of claim 8, wherein the output stage comprises:
a first resistor coupled between the first terminal of the first differential pair and a node;
a second resistor coupled between the second terminal of the second differential pair and the node;
a first transistor, wherein a first terminal of the first transistor is configured to receive a voltage, a second terminal of the first transistor is coupled to the first terminal of the first different pair, and a control terminal of the first transistor is coupled to the node; and
a second transistor, wherein a first terminal of the second transistor is configured to receive the voltage, a second terminal of the second transistor is coupled to the second terminal of the first different pair, and a control terminal of the second transistor is coupled to the node.

10. The phase interpolator of claim 9, wherein the output stage further comprises:
a third transistor, wherein a first terminal of the third transistor is configured to receive the voltage, a second terminal of the third transistor is configured to output the first output signal, and a control terminal of the third transistor is coupled to the first terminal of the first differential pair;
a fourth transistor, wherein a first terminal of the fourth transistor is configured to receive the voltage, a second terminal of the fourth transistor is configured to output the second output signal, and a control terminal of the fourth transistor is coupled to the second terminal of the first differential pair;
a fifth transistor, wherein a first terminal of the fifth transistor is coupled to the second terminal of the fourth transistor, and a second terminal of the fifth transistor is coupled to ground;
a sixth transistor, wherein a first terminal of the sixth transistor is coupled to the second terminal of the third transistor, and a second terminal of the sixth transistor is coupled to ground;
a seventh transistor, wherein a first terminal of the seventh transistor is configured to receive the voltage, and a control terminal of the seventh transistor is coupled to the first terminal of the first differential pair;
an eighth transistor, wherein a first terminal of the eighth transistor is configured to receive the voltage, and a control terminal of the eighth transistor is coupled to the second terminal of the first differential pair;
a ninth transistor, wherein a first terminal of the ninth transistor is coupled to a second terminal of the seventh transistor and a control terminal of the ninth transistor, a second terminal of the ninth transistor is coupled to ground, and the control terminal of the ninth transistor is coupled to a control terminal of the fifth transistor; and
a tenth transistor, wherein a first terminal of the tenth transistor is coupled to a second terminal of the eighth transistor and a control terminal of the tenth transistor, a second terminal of the tenth transistor is coupled to ground, and the control terminal of the tenth transistor is coupled to a control terminal of the sixth transistor.

11. A phase interpolator, comprising:
an input stage configured to generate a first signal and a second signal according to a first group of input signals and a second group of input signals;
a switching circuit configured to transmit the first signal and the second signal to a current source circuit and control a value of the first signal and a value of the second signal according to a plurality of control signals;
an output stage configured to generate a first output signal according to the first signal and the second signal; and
a correction circuit configured to provide and stable a common mode voltage of the first output signal with one of a feedback mechanism and an AC-coupling mechanism according to the first output signal.

12. The phase interpolator of claim 11, wherein in a condition that the correction circuit employs the feedback mechanism, the correction circuit comprises:
an amplifier coupled to the output stage, and configured to generate the common mode voltage according to the first output signal and a predetermined voltage.

13. The phase interpolator of claim 11, wherein in a condition that the correction circuit employs the AC-coupling mechanism, the correction circuit comprises:
a capacitor configured to receive the first output signal, and to output an AC signal;
a self-bias resistor configured to generate the common mode voltage according to the AC signal;
a buffer configured to generate a second output signal according to the AC signal; and
a buffering output circuit configured to output a third output signal based on the common mode voltage and the second output signal.

14. The phase interpolator of claim 11, wherein the input stage comprises a first differential pair and a second differential pair, the first differential pair is configured to generate the first signal according to the first group of input signals, the second differential pair is configured to generate the second signal according to the second group of input signals, and the switching circuit comprises:
a first switch configured to be selectively turned on or turned off according a first one of the control signals, in order to transmit the first signal from the first differential pair to the current source circuit; and
a second switch configured to be selectively turned on or turned off according a second one of the control signals, in order to transmit the second signal from the second differential pair to the current source circuit.

15. The phase interpolator of claim 11, further comprising:
a regulation circuit configured to stable the switching circuit and the current source circuit.

16. The phase interpolator of claim 15, wherein the regulation circuit comprises:
a first transistor coupled to the switching circuit at an node, and configured to transmit the first signal to the switching circuit based on a bias voltage; and
a first amplifier configured to generate the bias voltage according to a voltage level of the node and a reference voltage.

17. The phase interpolator of claim 11, wherein the output stage is configured to provide an active load, in order to generate the first output signal according to the first signal and the second signal.

18. The phase interpolator of claim 11, wherein the input stage comprises a first differential pair and a second differential pair, the first differential pair is configured to generate the first signal according to the first group of input signals, the second differential pair is configured to generate the second signal according to the second group of input signals, a first terminal of the first differential pair is coupled to a first terminal of the second differential pair, a second terminal of the first differential pair is coupled to a second terminal of the second differential pair, and the output stage is further configured to generate a second output signal according to the first signal and the second signal.

19. The phase interpolator of claim 18, wherein the output stage comprises:
a first resistor coupled between the first terminal of the first differential pair and a node;
a second resistor coupled between the second terminal of the second differential pair and the node;
a first transistor, wherein a first terminal of the first transistor is configured to receive a voltage, a second terminal of the first transistor is coupled to the first terminal of the first different pair, and a control terminal of the first transistor is coupled to the node; and
a second transistor, wherein a first terminal of the second transistor is configured to receive the voltage, a second terminal of the second transistor is coupled to the second terminal of the first different pair, and a control terminal of the second transistor is coupled to the node.

20. The phase interpolator of claim 19, wherein the output stage further comprises:
a third transistor, wherein a first terminal of the third transistor is configured to receive the voltage, a second terminal of the third transistor is configured to output the first output signal, and a control terminal of the third transistor is coupled to the first terminal of the first differential pair;
a fourth transistor, wherein a first terminal of the fourth transistor is configured to receive the voltage, a second terminal of the fourth transistor is configured to output the second output signal, and a control terminal of the fourth transistor is coupled to the second terminal of the first differential pair;
a fifth transistor, wherein a first terminal of the fifth transistor is coupled to the second terminal of the fourth transistor, and a second terminal of the fifth transistor is coupled to ground;
a sixth transistor, wherein a first terminal of the sixth transistor is coupled to the second terminal of the third transistor, and a second terminal of the sixth transistor is coupled to ground;
a seventh transistor, wherein a first terminal of the seventh transistor is configured to receive the voltage, and a control terminal of the seventh transistor is coupled to the first terminal of the first differential pair;
an eighth transistor, wherein a first terminal of the eighth transistor is configured to receive the voltage, and a control terminal of the eighth transistor is coupled to the second terminal of the first differential pair;
a ninth transistor, wherein a first terminal of the ninth transistor is coupled to a second terminal of the seventh transistor and a control terminal of the ninth transistor, a second terminal of the ninth transistor is coupled to ground, and the control terminal of the ninth transistor is coupled to a control terminal of the fifth transistor; and
a tenth transistor, wherein a first terminal of the tenth transistor is coupled to a second terminal of the eighth transistor and a control terminal of the tenth transistor, a second terminal of the tenth transistor is coupled to ground, and the control terminal of the tenth transistor is coupled to a control terminal of the sixth transistor.
